(19) United States
(12) Patent Application Publication
(10) Pub. No.: US 2023/0411464 A1
(43) Pub. Date: Dec. 21, 2023

(54) SHARED-DIELECTRIC MOSFET DEVICE WITH RESISTIVE-FIELD-PLATE AND PREPARATION METHOD THEREOF

(71) Applicant: NO.24 RESEARCH INSTITUTE OF CHINA ELECTRONICS TECHNOLOGY GROUP CORPORATION, Chongqing (CN)

(72) Inventors: Kaizhou TAN, Chongqing (CN); Tian XIAO, Chongqing (CN); Jiahao ZHANG, Chongqing (CN); Xiaoquan LI, Chongqing (CN); Pengfei WANG, Chongqing (CN); Ying PEI, Chongqing (CN); Guangbo LI, Chongqing (CN); Yonghui YANG, Chongqing (CN); Hequan JIANG, Chongqing (CN); Peijian ZHANG, Chongqing (CN); Sheng QIU, Chongqing (CN); Liang CHEN, Chongqing (CN); Wei CUI, Chongqing (CN)

(73) Assignee: NO.24 RESEARCH INSTITUTE OF CHINA ELECTRONICS TECHNOLOGY GROUP CORPORATION, Chongqing (CN)

(21) Appl. No.: 18/035,758

(22) PCT Filed: Nov. 1, 2021
(86) PCT No.: PCT/CN2021/127968

§ 371 Date: May 8, 2023

(30) Foreign Application Priority Data
Nov. 6, 2020 (CN) 202011233504X

(51) Int. Cl. H01L 29/40; H01L 29/78; H01L 29/66

(52) U.S. Cl. CPC H01L 29/405; H01L 29/407; H01L 29/7813; H01L 29/401; H01L 29/66734

(57) ABSTRACT

A shared-dielectric MOSFET device with a resistive-field-plate and a preparation method are provided. In the shared-dielectric MOSFET device, the semi-insulating resistive-field-plate electrically connected to the trench gate structure and the drain structure is introduced in the drift region of the existing trench gate MOS devices, and when the trench gate structure controls the MOS channel to be turned on or turned off, the semi-insulating resistive-field-plate can adjust the doping concentration of the drift region, to modulate the conductance of the on-state drift region and the distribution of a off-state high-voltage blocking electric field, thereby obtaining a lower on-resistance. Meanwhile, in the preparation method of the present disclosure, the modern 2.5-dimensional processing technology based on deep trench etching is adopted, which is conducive to miniaturization designs and high density designs of the structure and is more suitable for the More than Moore development of modern integrated semiconductor devices.

### TECHNICAL FIELD

The present disclosure relates to the field of semiconductor devices and integrated circuits, and in particular, to a metal-oxide-semiconductor field-effect transistor (MOSFET) device with a resistive-field-plate and a preparation method thereof.

### BACKGROUND

For semiconductor devices, especially high-voltage silicon power devices, the optimal design of a breakdown voltage and on-resistance of a drift region used to withstand voltage are often mutually influential and contradictory, in other words, it is typically difficult to obtain a high breakdown voltage and a low on-resistance in the drift region at the same time. However, there is an exception where the drift region subjected to withstand voltage has minority carriers or non-equilibrium dual-carriers for high-level injection modulation when the devices (for example, insulated gate bipolar transistors (IGBT), positive-intrinsic-negative diodes (PIN), gate turn-off thyristors (GTO), and the like) are turned on. Generally, in high-voltage semiconductor silicon devices above 300V, a part of the on-resistance is occupied by the high-voltage drift region of these devices, which becomes increasingly serious with an increase in their operating voltage. This is a famous limitation of silicon theory in non-minority carrier modulated power devices, where the 2.5th power of the breakdown voltage is proportional to the on-resistance of the drift region.

To reduce the on-resistance of the drift region of the non-minority carrier modulated power devices in a high-voltage situation, some methods and new device cellular structures for reducing the on-resistance with the constant breakdown voltage have been proposed in the past ten years, and the most famous device is an improved super junction structure based on a two-dimensional electric field principle and a charge balance principle of semiconductor PN junction reduced surface field (RESURF).

There are three types of super junction structures or structures with super junction-like effects currently known: the first type of structure is based on PN junctions; in the second type of structure, the P-type or N-type region in the first type of structure is replaced by a dielectric material with a very high dielectric constant, and the dielectric material with a very high dielectric constant can include a thin layer of a dielectric material with a typical dielectric constant along an interface of the P-type or N-type region; the third type of structure is also based on the PN junction structure in the first type, where the P-type or N-type region is replaced by a thin layer of a dielectric material with a typical dielectric constant and a semi-insulating material layer structure that are along the interface of the P-type or N-type region, and the thin layer of the dielectric material with a typical dielectric constant and the semi-insulating material layer structure act as a resistive field plate.

However, great research progress has not yet been made for the second type of structure with super junction-like effects, and there are no experimental results or specific implementation schemes for the dielectric material with a high dielectric constant or the semi-insulating material layer structure. Therefore, how to obtain high-voltage silicon power devices, such as MOS devices, with a high breakdown voltage and a low on-resistance based on the existing super junction structures is an urgent problem to be solved.

### SUMMARY

The present disclosure provides a shared-dielectric MOSFET device with a resistive-field-plate and a preparation method of the shared-dielectric MOSFET device with the resistive-field-plate, which are for solving the above problems.

The present disclosure provides the shared-dielectric MOSFET device with the resistive-field-plate, including:

a substrate;

an epitaxial layer, disposed over the substrate;

a MOS source region, disposed in a top portion of the epitaxial layer;

a MOS channel region, disposed in the epitaxial layer and below the MOS source region;

a trench gate structure, disposed on the top portion of the epitaxial layer; wherein the trench gate structure covers side surfaces of the MOS source region and the MOS channel region; and

a semi-insulating resistive-field-plate structure, disposed in the epitaxial layer and located below the trench gate structure; wherein the semi-insulating resistive-field-plate structure is electrically connected to the substrate, and an end of the semi-insulating resistive-field-plate structure away from the substrate is electrically connected to the trench gate structure;

wherein the trench gate structure and the semi-insulating resistive-field-plate structure share an isolation dielectric layer;

wherein a trench is formed in the epitaxial layer, and the trench vertically extends through the MOS source region, the MOS channel region, and the epitaxial layer to the substrate; the semi-insulating resistive-field-plate structure and the trench gate structure are sequentially disposed in the trench along a bottom-to-top direction of the trench.

In an embodiment, the semi-insulating resistive-field-plate structure includes the isolation dielectric layer and a semi-insulating resistive-field-plate layer whose side wall is surrounded by the isolation dielectric layer, and the trench gate structure includes the isolation dielectric layer and a first trench gate layer; wherein the first trench gate layer is electrically connected to the semi-insulating resistive-field-plate layer, and the semi-insulating resistive-field-plate layer is electrically connected to the substrate at a bottom of the trench.

In an embodiment, the semi-insulating resistive-field-plate structure includes the isolation dielectric layer and a semi-insulating resistive-field-plate layer whose side wall is surrounded by the isolation dielectric layer, and the trench gate structure includes the isolation dielectric layer, a second trench gate layer, and a third trench gate layer; wherein the second trench gate layer is electrically connected to the semi-insulating resistive-field-plate layer, and the semi-insulating resistive-field-plate layer is electrically connected to the substrate at a bottom of the trench.

In an embodiment, further including:

a MOS channel contact region, disposed in the top portion of the epitaxial layer; wherein the MOS channel contact region is in contact with the MOS channel region.

In an embodiment, further including:

a source electrode, disposed over the MOS channel contact region and electrically connected to the MOS source region;

a gate electrode, disposed over the trench gate structure and electrically connected to the trench gate structure; and

a drain electrode, disposed on a side of the substrate away from the epitaxial layer.

The present disclosure also provides the preparation method of the shared-dielectric MOSFET device with the resistive-field-plate, including:

providing a substrate and forming an epitaxial layer on the substrate;

forming a MOS channel region, a MOS source region, and a MOS channel contact region within a top portion of the epitaxial layer;

forming a trench in the epitaxial layer; wherein the trench vertically extends through the MOS source region, the MOS channel region, and the epitaxial layer to the substrate;

sequentially forming a semi-insulating resistive-field-plate structure and a trench gate structure in the trench along a bottom-to-top direction of the trench; wherein the semi-insulating resistive-field-plate structure is electrically connected to the trench gate structure, and an end of the semi-insulating resistive-field-plate structure away from the trench gate structure is electrically connected to the substrate; and

forming a source electrode, a gate electrode, and a drain electrode;

wherein the trench gate structure and the semi-insulating resistive-field-plate structure share an isolation dielectric layer.

In an embodiment, the step of forming the MOS channel region, the MOS source region, and the MOS channel contact region within the top portion of the epitaxial layer includes:

forming the MOS channel region within the top portion of the epitaxial layer by a first ion implantation and a first ion diffusion;

forming the MOS source region disposed over the MOS channel region by a second ion implantation; and

forming the MOS channel contact region by a third ion implantation;

wherein the MOS channel contact region is in contact with the MOS channel region.

In an embodiment, the step of sequentially forming the semi-insulating resistive-field-plate structure and the trench gate structure in the trench along the bottom-to-top direction of the trench includes:

oxidating a bottom and a sidewall of the trench to form the isolation dielectric layer;

etching and removing part of the isolation dielectric layer at the bottom of the trench;

filling the trench to form a semi-insulating resistive-field-plate layer; wherein a top surface of the semi-insulating resistive-field-plate layer is lower than a bottom surface of the MOS channel region; and

forming a first trench gate layer over the semi-insulating resistive-field-plate layer and electrically connected to the semi-insulating resistive-field-plate layer;

wherein the semi-insulating resistive-field-plate layer and the isolation dielectric layer constitute the semi-insulating resistive-field-plate structure, and the first trench gate layer and the isolation dielectric layer constitute the trench gate structure.

In an embodiment, the step of sequentially forming the semi-insulating resistive-field-plate structure and the trench gate structure in the trench along the bottom-to-top direction of the trench includes:

oxidating a bottom and a sidewall of the trench to form the isolation dielectric layer;

etching and removing part of the isolation dielectric layer at the bottom of the trench;

filling the trench to form a semi-insulating resistive-field-plate layer; wherein a top surface of the semi-insulating resistive-field-plate layer is lower than a bottom surface of the MOS channel region; and

sequentially forming a second trench gate layer and a third trench gate layer over the semi-insulating resistive-field-plate layer; wherein a sidewall of the second trench gate layer is surrounded by the isolation dielectric layer, a sidewall of the third trench gate layer is surrounded by the second trench gate layer, and a bottom of the second trench gate layer is electrically connected to the semi-insulating resistive-field-plate layer;

wherein the semi-insulating resistive-field-plate layer and the isolation dielectric layer constitute the semi-insulating resistive-field-plate structure; the second trench gate layer, the third trench gate layer, and the isolation dielectric layer constitute the trench gate structure.

In an embodiment, the step of forming the semi-insulating resistive-field-plate structure in the trench includes:

filling the trench with a semi-insulating polysilicon material;

etching and removing a part of the semi-insulating polysilicon material filled in the trench, so that a top surface of remaining semi-insulating polysilicon material filled in the trench is below the bottom surface of the MOS channel region;

wherein the top surface of the remaining semi-insulating polysilicon material filled in the trench is the top surface of the semi-insulating resistive-field layer.

In an embodiment, the step of forming the first trench gate layer over the semi-insulating resistive-field-plate layer includes:

filling a first doped polysilicon material in the trench over the semi-insulating resistive-field-plate layer, wherein the first doped polysilicon material at least covers the top surface of the semi-insulating resistive-field-plate layer; and

etching the first doped polysilicon material to form the first trench gate layer.

In an embodiment, the step of sequentially forming the second trench gate layer and the third trench gate layer over the semi-insulating resistive-field-plate layer includes:

filling a second doped polysilicon material in the trench over the semi-insulating resistive-field-plate layer, wherein the second doped polysilicon material at least covers the top surface of the semi-insulating resistive-field-plate layer, and part of the sidewall of the trench not covered by the semi-insulating resistive-field-plate layer;

filling a third doped polysilicon material over the second doped polysilicon material, wherein the semi-insulating resistive-field-plate layer, the second doped polysilicon material, and the third doped polysilicon material at least fill the trench; and

etching the third doped polysilicon material to form the third trench gate layer, and etching the second doped polysilicon material to form the second trench gate layer.

As described above, the shared-dielectric MOSFET device with the resistive-field-plate and the preparation method thereof of the present disclosure has the following beneficial effects:

1) The semi-insulating resistive-field-plate electrically connected to the trench gate structure and the drain structure is introduced in the drift region of the existing trench gate MOS devices, and when the trench gate structure controls the MOS channel to be turned on or turned off, the semi-insulating resistive-field-plate can adjust the doping concentration of the drift region, to modulate the conductance of the on-state drift region and the distribution of a off-state high-voltage blocking electric field, thereby obtaining a lower on-resistance.

2) The modern 2.5-dimensional processing technology based on deep trench etching is adopted in the present disclosure, which is conducive to miniaturization designs and high density designs of the structure and is more suitable for the More than Moore development of modern integrated semiconductor devices.

### BRIEF DESCRIPTION OF THE DRAWINGS

FIG. 1 is a schematic structural diagram of a shared-dielectric MOSFET device with a resistive-field-plate according to an embodiment of the present disclosure.

FIG. 2 is a flowchart of a preparation method of a shared-dielectric MOSFET device with a resistive-field-plate according to an embodiment of the present disclosure.

FIGS. 3-17 show intermediate structures obtained after various steps of a preparation method of a shared-dielectric MOSFET device with a resistive-field-plate according to Embodiment 1 of the present disclosure.

FIG. 18 is a schematic structural diagram of a shared-dielectric MOSFET device with a resistive-field-plate according to Embodiment 2 of the present disclosure.

FIGS. 19-22 are show intermediate structures obtained after various steps of a preparation method of a shared-dielectric MOSFET device with a resistive-field-plate according to Embodiment 2 of the present disclosure.

Reference Numerals

| | |
|---|---|
| 1 | Substrate |
| 2 | Epitaxial layer |
| 20, 20′ | Oxide layer |
| 21 | MOS channel region |
| 22 | MOS source region |
| 23 | MOS channel contact region |
| 3 | Semi-insulating resistive-field-plate structure |
| 4 | Trench gate structure |
| 30 | Semi-insulating polysilicon material |
| 300 | Isolation dielectric layer |
| 31 | Semi-insulating resistive-field-plate layer |
| 401 | First doped polysilicon material |
| 402 | Second doped polysilicon material |
| 403 | Third doped polysilicon material |
| 41 | First trench gate layer |
| 42 | Second trench gate layer |
| 43 | Third trench gate layer |
| 50 | Isolation dielectric layer |
| 5 | Source electrode |
| T | Trench |

### DETAILED DESCRIPTION

In the existing super junction structure devices or super junction-like structure devices, the optimization of the breakdown voltage and the on-resistance of the devices has reached a bottleneck due to their contradictory relationship, and it is becoming more and more difficult to further reduce the on-resistance while keeping the breakdown voltage unchanged.

In order to solve the above problem, the present disclosure provides a shared-dielectric MOSFET device with a resistive-field-plate: a semi-insulating resistive-field-plate electrically connected to a trench gate structure and a drain structure is added to a drift region of the existing trench gate MOS devices, and the semi-insulating resistive-field-plate can modulate the conductance of the on-state drift region and the distribution of the off-state high-voltage blocking electric field to obtain a lower on-resistance.

The present disclosure will be described below through specific examples. Those skilled in the art can easily understand the other advantages and effects of the present disclosure according to contents disclosed in the specification. The present disclosure may also be implemented or applied through other different embodiments, and various modifications or changes may be made to all details in the specification based on different points of view and applications without departing from the spirit of the present disclosure.

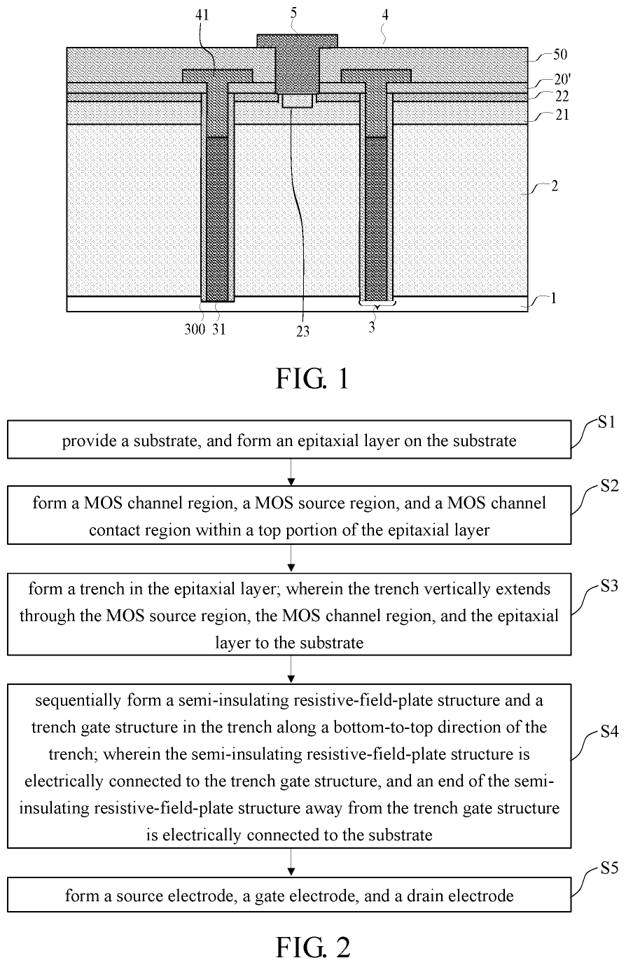

Refer to FIGS. 1-22. It should be noted that the drawings provided herein only exemplify the basic idea of the present disclosure. Only components closely related to the present disclosure are shown in the drawings, and they are not necessarily drawn according to the quantities, shapes, and sizes of the components during actual implementation. During actual implementation, the patterns, quantities, and proportions of the components may be changed as needed, and the layout of the components may also be more complicated. It should be noted that the structure, proportion, size, etc. illustrated in the drawings of this specification are only used to match the contents disclosed in the specification for the understanding and reading of those skilled in the art, and are not used to limit the conditions under which the present disclosure can be implemented. Any modification of the structure, change of proportion or adjustment of the size, without affecting the efficacy of the present disclosure and the purpose it can achieve, should still fall within the scope of the technical contents disclosed in the present disclosure.

### Embodiment 1

As shown in FIG. 1, the present disclosure provides a shared-dielectric MOSFET device with a resistive-field-plate. The shared-dielectric MOSFET device includes:

a substrate 1;

an epitaxial layer 2, disposed over the substrate 1;

a MOS source region 22, disposed in a top portion of the epitaxial layer 2;

a MOS channel region 21, disposed in the epitaxial layer 2 and below the MOS source region 22;

a trench gate structure 4, disposed on the top portion of the epitaxial layer 2;

wherein the trench gate structure 4 covers side surfaces of the MOS source region 22 and the MOS channel region 21; and

a semi-insulating resistive-field-plate structure 3, disposed in the epitaxial layer 2 and located below the trench gate structure 4, wherein the semi-insulating resistive-field-plate structure 3 is electrically connected to the substrate 1, and an end of the semi-insulating resistive-field-plate structure 4 away from the substrate 1 is electrically connected to the trench gate structure 4.

The trench gate structure 4 and the semi-insulating resistive-field-plate structure 3 share an isolation dielectric layer 300.

A trench is formed in the epitaxial layer 2, and the trench vertically extends through the MOS source region 22, the MOS channel region 21, and the epitaxial layer 2 to the substrate 1; the semi-insulating resistive-field-plate structure 3 and the trench gate structure 4 are sequentially disposed in the trench along a bottom-to-top direction of the trench.

In an embodiment, as shown in FIG. 1, the semi-insulating resistive-field-plate structure 3 includes the isolation dielectric layer 300 and a semi-insulating resistive-field-plate layer 31 whose side wall is surrounded by the isolation dielectric layer 300, and the trench gate structure 4 includes the isolation dielectric layer 300 and a first trench gate layer 41; the first trench gate layer 41 is electrically connected to the semi-insulating resistive-field-plate layer 31, and the semi-insulating resistive-field-plate layer 31 is electrically connected to the substrate 1 at a bottom of the trench.

In an embodiment, as shown in FIG. 1, the shared-dielectric MOSFET device further includes:

a MOS channel contact region 23, disposed in the top portion of the epitaxial layer 2, wherein the MOS channel contact region 23 is in contact with the MOS channel region 21.

In an embodiment, as shown in FIG. 1, the shared-dielectric MOSFET device further includes:

a source electrode 5, disposed over the MOS channel contact region 23 and electrically connected to the MOS source region 22;

a gate electrode (not shown in FIG. 1), disposed over the trench gate structure and electrically connected to the trench gate structure; and

a drain electrode (not shown in FIG. 1), disposed on a side of the substrate away from the epitaxial layer.

As shown in FIG. 2, the present disclosure provides a preparation method of the shared-dielectric MOSFET device with the resistive-filed-plate, which includes:

step S1, providing a substrate 1, and forming an epitaxial layer 2 on the substrate 1;

step S2, forming a MOS channel region 21, a MOS source region 22, and a MOS channel contact region 23 within a top portion of the epitaxial layer 2;

step S3, forming a trench T in the epitaxial layer 2, wherein the trench T vertically extends through the MOS source region 22, the MOS channel region 21, and the epitaxial layer 2 to the substrate 1;

step S4, sequentially forming a semi-insulating resistive-field-plate structure 3 and a trench gate structure 4 in the trench T along a bottom-to-top direction of the trench T, wherein the semi-insulating resistive-field-plate structure 3 is electrically connected to the trench gate structure 4, and an end of the semi-insulating resistive-field-plate structure 3 away from the trench gate structure 4 is electrically connected to the substrate 1; and

step S5, forming a source electrode 5, a gate electrode, and a drain electrode.

The trench gate structure 4 and the semi-insulating resistive-field-plate structure 3 share an isolation dielectric layer 300.

The implementation of the technical solution in the present disclosure is described below by taking an N-channel high-voltage MOSFET device as an example, and other technical solutions that can realize the content of the present disclosure should fall within the scope of the present disclosure. The structure of a P-channel high-voltage MOSFET device is the same as that of the N-channel high-voltage MOSFET device, and the difference between the P-channel high-voltage MOSFET device and the N-channel high-voltage MOSFET device is that the types of doped impurities are different; according to different process properties of P-type impurities and N-type impurities, the P-channel high-voltage MOSFET device can be prepared by adjusting the process of preparing the N-channel high-voltage MOSFET device, which is well known to those skilled in the art.

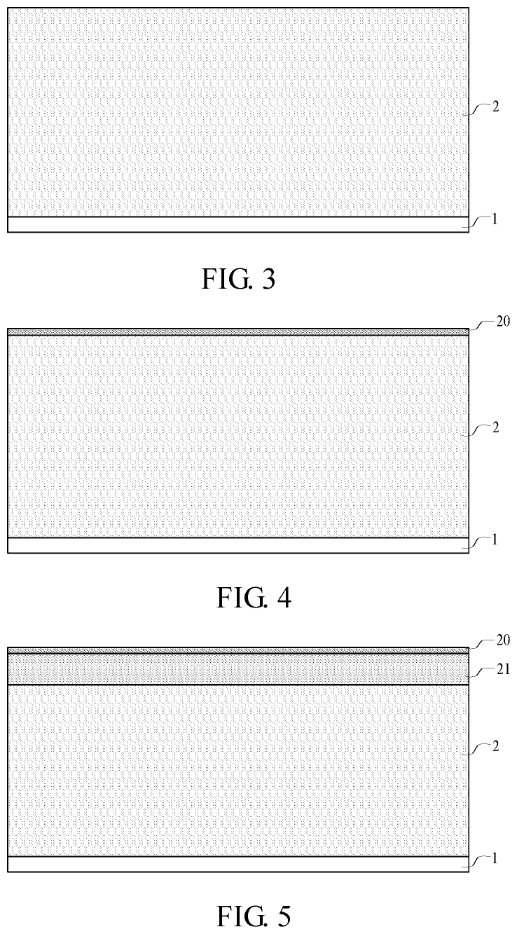

In an embodiment, as shown in FIG. 3, in step S1, the substrate 1 is provided as a drain region of the shared-dielectric MOSFET device, and the substrate 1 is an N-type doped semiconductor material (e.g., silicon, silicon carbide, gallium arsenide, etc.); the epitaxial layer 2 is disposed over the substrate 1 as a drift region of the shared-dielectric MOSFET device, and the epitaxial layer 2 also is an N-type doped semiconductor material.

The substrate 1 is heavily doped, and the epitaxial layer 2 is lightly doped. The thickness of the epitaxial layer 2 can be flexibly designed according to the situation, for example, when the breakdown voltage is as high as 300 V, the thickness of the epitaxial layer 2 can be designed to be 20 μm.

In an embodiment, between step S1 and step S2, the preparation method of the shared-dielectric MOSFET device with the resistive-field-plate further includes: forming a photolithographic alignment mark on the epitaxial layer 2, so as to facilitate the alignment in subsequent process steps.

In an embodiment, as shown in FIG. 4, between step S1 and step S2, the preparation method of the shared-dielectric MOSFET device with the resistive-field-plate further includes: oxidating a top portion of the epitaxial layer 2 to form an oxide layer 20, for example, the oxide layer 20 with a thickness of about 60 nm±10 nm can be obtained by implementing a wet oxidation at 950° C. for 20 min.

In an embodiment, as shown in FIGS. 5-7, the step S2 of forming the MOS channel region 21, the MOS source region 22, and the MOS channel contact region 23 within the top portion of the epitaxial layer 2 further includes:

step S21, as shown in FIG. 5, forming the MOS channel region 21 within the top portion of the epitaxial layer 2 by a first ion implantation and a first ion diffusion;

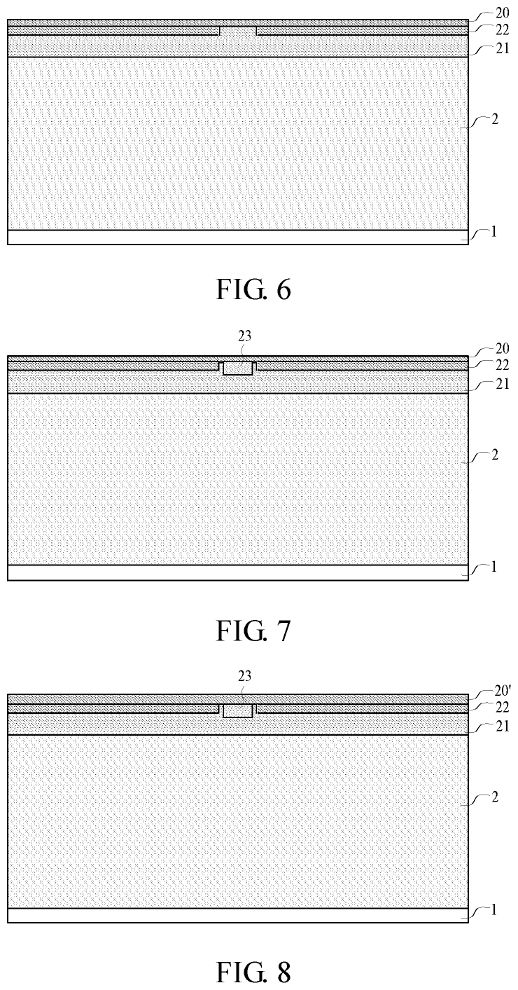

step S22, as shown in FIG. 6, forming the MOS source region 22 over the MOS channel region 21 by a second ion implantation;

step S23, as shown in FIG. 7, forming the MOS channel contact region 23 by a third ion implantation, wherein the MOS channel contact region 23 is in contact with the MOS channel region 21.

In an embodiment, as shown in FIG. 5, in step S21, the first ion implantation is implemented, for example, boron ion implantation is implemented under the conditions of 100 Key and 5×1013 cm−2, and then the first ion diffusion is implemented at 1050° C. for 90 min under the protection of inert gas, to form a P-type doped MOS channel region 21 within the top portion of the epitaxial layer 2.

In an embodiment, as shown in FIG. 6, in step S22, lithography of the source region is performed by using a photoresist as a shielding mask, and then the second ion implantation is implemented (for example, arsenic ion implantation is implemented under the conditions of 170 Key and 5×1015 cm−2), to form the MOS source region 22.

In an embodiment, as shown in FIG. 7, in step S23, lithography of the channel contact region is performed by using a photoresist as a shielding mask, and then the third ion implantation is implemented (for example, boron ion implantation is implemented under the conditions of 80 Key and 3×1015 cm−2), to form the MOS channel contact region 23; the MOS channel contact region 23 is in contact with the MOS channel region 21.

When the doping concentration of the impurity of the MOS channel region 21 is sufficient to form an electrical connection (i.e., ohmic contact), the MOS channel contact region 23 can be omitted.

In an embodiment, as shown in FIG. 8, between step S2 and step S3, the preparation method of the shared-dielectric MOSFET device with the resistive-field-plate further includes: in order to maintain a shallow junction depth and make full use of the epitaxial layer 2, forming another oxide layer with a thickness of 450 nm±50 nm over the oxide layer 20 by low pressure chemical vapor deposition (LPCVD), and the another oxide layer and the oxide layer 20 are collectively referred to as the oxide layer 20′ whose thickness is greater than the oxide layer 20; the oxide layer 20′ is a foundation for etching a hard masking layer of the trench T.

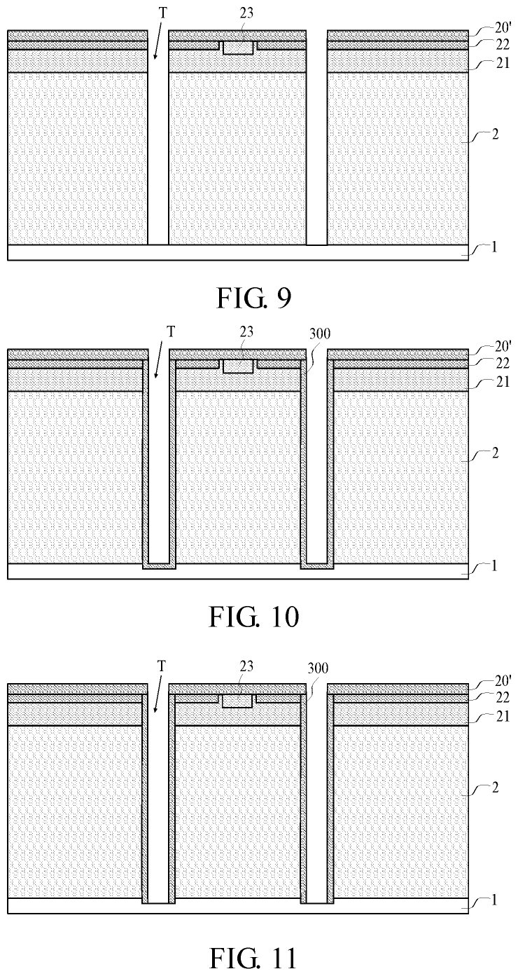

In an embodiment, in step S3, the position of the trench T to be formed is exposed by using a lithography machine and the corresponding mask, and then the trench T is formed by dry etching; the trench T vertically extends from the oxide layer 20′, the MOS source region 22, the MOS channel region 21, and the epitaxial layer 2 to the substrate 1, as shown in FIG. 9.

The specific parameters (including the number of sub trenches, depth, and width of the trench T) of the trench T need to be designed according to the working voltage of the high-voltage MOSFET device and the process implementation capability, meanwhile, the size of the semi-insulating resistive-field-plate structure 3 and the trench gate structure 4 formed in the same trench T and the optimal area required by the shared-dielectric MOSFET device need to be considered in the design process. In an embodiment, the depth of the trench T is 22 μm and the width of the trench T is 1.5˜2 μm.

In an embodiment, as shown in FIGS. 10-16, step S4 of sequentially forming the semi-insulating resistive-field-plate structure 3 and the trench gate structure 4 in the trench T along the bottom to the top direction of the trench T further includes:

step S41, as shown in FIG. 10, oxidating a bottom and a sidewall of the trench T to form the isolation dielectric layer 300;

step S42, as shown in FIG. 11, etching and removing part of the isolation dielectric layer 300 at the bottom of the trench T;

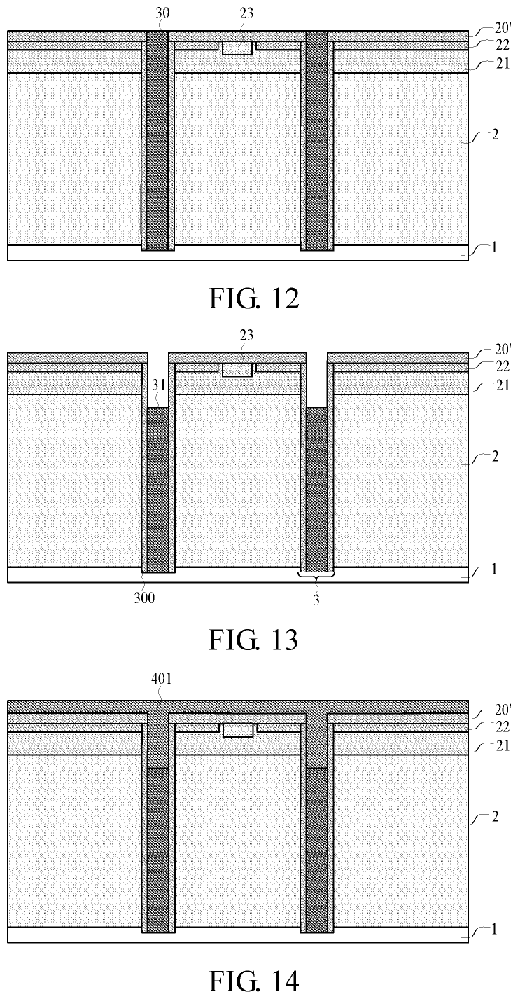

step S43, as shown in FIGS. 12-13, filling the trench T to form a semi-insulating resistive-field-plate layer 31, wherein a top surface of the semi-insulating resistive-field-plate layer 31 is lower than a bottom surface of the MOS channel region 21;

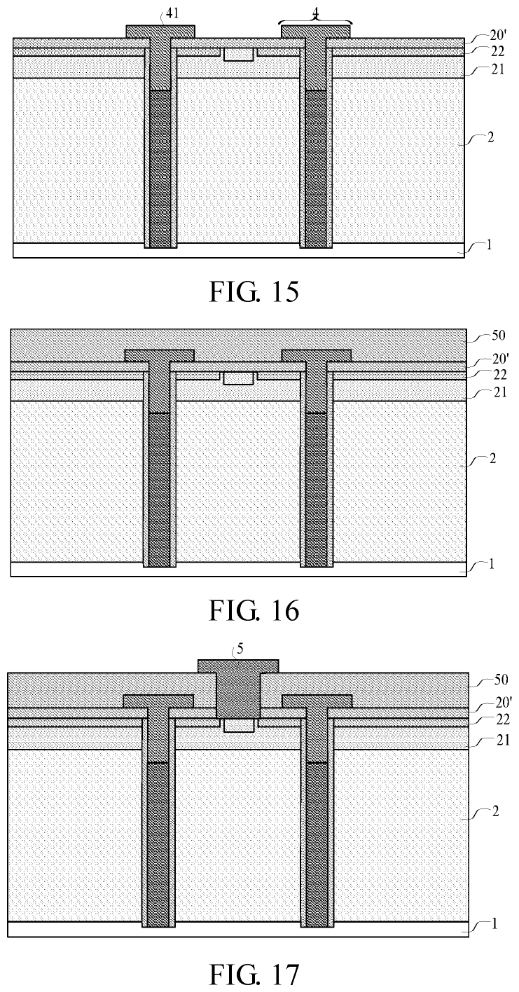

step S44, as shown in FIGS. 14-15, forming a first trench gate layer 41 over the semi-insulating resistive-field-plate layer 31 and electrically connected to the semi-insulating resistive-field-plate layer 31,

wherein the semi-insulating resistive-field-plate layer 31 and the isolation dielectric layer 300 constitute the semi-insulating resistive-field-plate structure 3, and the first trench gate layer 41 and the isolation dielectric layer 300 constitute the trench gate structure 4.

In an embodiment, as shown in FIG. 10, in step S41, the bottom and the sidewall of the trench T are oxidized, to form the isolation dielectric layer 300, and the isolation dielectric layer 300 acts as an oxidized dielectric layer of the semi-insulating resistive-field-plate structure 3 and the trench gate structure 4; for example, an isolation dielectric layer 300 with a thickness of 120 nm-140 nm can be formed by implementing a chlorine-doped dry oxidation at 1050° C. for 150 min.

In an embodiment, as shown in FIG. 11, in step S42, the isolation dielectric layer 300 at the bottom of the trench T is removed through anisotropic dry etching, and the isolation dielectric layer 300 at the sidewall of the trench T remains.

In an embodiment, as shown in FIGS. 12-13, step S43 of forming the semi-insulating resistive-field-plate layer 31 in the trench T further includes:

step S431, as shown in FIG. 12, filling the trench T with a semi-insulating polysilicon material 30; for example, the semi-insulating polysilicon material 30 with a deposition thickness of 1.1 μm±0.1 μm is formed in the trench T by LPCVD;

step S432, as shown in FIG. 13, reversely etching the semi-insulating polysilicon material 30 to expose a top surface of the oxide layer 20′, and then etching and removing a part of the semi-insulating polysilicon material 30 filled in the trench T, so that a top surface of remaining semi-insulating polysilicon material 30 filled in the trench T is below the bottom surface of the MOS channel region 21;

The top surface of the remaining semi-insulating polysilicon material 30 filled in the trench T is the top surface of the semi-insulating resistive-field layer 31, and the remaining semi-insulating polysilicon material 30 filled in the trench T is the semi-insulating resistive-field-plate layer 31; when etching a part of the semi-insulating polysilicon material 30 filled in the trench T, it is necessary to control an etching depth (in other words, the top surface of the semi-insulating resistive-field-plate layer 31 is not higher, or slightly lower than the bottom surface of MOS channel region 21), so that the trench gate structure 4 can cover the sidewall of the MOS channel region 21 formed by double diffusion in the vertical direction, to ensure that the on and off of the MOS channel region 21 can be controlled by the trench gate structure 4.

In an embodiment, as shown in FIGS. 14-15, step S44 of forming the first trench gate layer 41 over the semi-insulating resistive-field-plate layer 31 further includes:

step S441, as shown in FIG. 14, filling a first doped polysilicon material 401 in the trench T over the semi-insulating resistive-field-plate layer 31; wherein the first doped polysilicon material 401 at least covers the top surface of the semi-insulating resistive-field-plate layer 31; and

step S442, as shown in FIG. 15, etching the first doped polysilicon material 401 to form the first trench gate layer 41 electrically connected to the semi-insulating resistive-field-plate layer 31.

In an embodiment, as shown in FIG. 14, in step S441, the first doped polysilicon material 401 is filled in the trench T over the semi-insulating resistive-field-plate layer 31 by deposition, and the first doped polysilicon material 401 at least covers the top surface of the semi-insulating resistive-field-plate layer 31 and part of the sidewall of the trench T not covered by the semi-insulating resistive-field-plate layer 31; for example, the first doped polysilicon material 401 with a thickness of 1.1 μm±0.1 μm can be filled in the trench T by low-pressure chemical vapor in-situ phosphorus doping deposition, and if there is no in-situ doping equipment, a phosphorus diffusion doping can be performed after the first doped polysilicon material 401 is deposited.

In an embodiment, as shown in FIG. 15, in step S442, the first doped polysilicon material 401 is etched by photolithography and dry etching, to form the first trench gate layer 41, and the first trench gate layer 41 is electrically connected to the semi-insulating resistive-field-plate layer 31.

In an embodiment, in step S5, an isolation dielectric layer 50 is firstly formed over the oxide layer 20′ and the trench gate structure 4 first by deposition; a source contact hole and a gate contact hole are secondly formed in the isolation dielectric layer 50; then, a metal layer is formed in the source contact hole and the gate contact hole by deposition, and photolithography of the metal layer is performed to respectively form a source electrode and a gate electrode thirdly; and finally, another metal layer is deposited on the side of the substrate 1 away from the epitaxial layer 2, to form a drain electrode.

In an embodiment, as shown in FIGS. 16-17, the isolation dielectric layer 50 is firstly formed over the oxide layer 20′ and the trench gate structure 4 by deposition; the source contact hole is then formed in the isolation dielectric layer 50 secondly; and then photolithography of the metal layer is performed to form the source electrode 5. The process of forming the gate electrode is similar to that of the source electrode.

In the shared-dielectric MOSFET device with the resistive-field-plate shown in FIG. 1 or FIG. 17, the semi-insulating resistive-field-plate electrically connected to the trench gate structure and the drain structure is added in the drift region of the existing trench gate MOS devices; when the trench gate structure controls the MOS channel to be turned on or turned off, the semi-insulating resistive-field-plate can modulate the conductance of the on-state drift region and the distribution of the off-state high-voltage blocking electric field, to obtain a lower on-resistance. Compared to the first-generation PN-junction-type superjunction devices, the shared-dielectric MOSFET device's ability to output current has been increased by 70% to 105% under the same process and design parameters; meanwhile, the modern 2.5-dimensional processing technology based on deep trench etching is adopted in the present disclosure, which is conducive to miniaturization designs and high-density designs of the structure.

Furthermore, it should be noted that the well-known and obvious industry general processes and conditions (e.g., cleaning) are omitted in the steps of the above embodiments, which are known to those skilled in the art. For those skilled in the art, suitable modifications of the structure of the shared-dielectric MOSFET device of the present disclosure can also be applied to the design of voltage withstanding drift regions, such as diodes, Schottky diodes, and collector regions of triodes, under the condition of low-level injection of minority carriers.

### Embodiment 2

The trench gate structure 4 of the Embodiment 1 of the present disclosure only includes the first trench gate layer 41 and the isolation dielectric layer 300, which is a single doped polysilicon gate structure. An external voltage can be applied to the first trench gate layer 41 to turn on or off a conductive channel in the MOS channel region 21 close to the isolation dielectric layer 300. In order to further improve the electrical control performance of the trench gate structure 4, Embodiment 2 of the present disclosure provides another shared-dielectric MOSFET device with the resistive-field-plate based on a secondary doped polysilicon gate structure.

As shown in FIG. 18, the present disclosure provides a shared-dielectric MOSFET device with a resistive-field-plate, including:

a substrate 1;

an epitaxial layer 2, disposed over the substrate 1;

a MOS source region 22, disposed in a top portion of the epitaxial layer 2;

a MOS channel region 21, disposed in the epitaxial layer 2 and below the MOS source region 22;

a trench gate structure 4, disposed on the top portion of the epitaxial layer 2;

wherein the trench gate structure 4 covers side surfaces of the MOS source region 22 and the MOS channel region 21; and

a semi-insulating resistive-field-plate structure 3, disposed in the epitaxial layer 2 and located below the trench gate structure 4; wherein the semi-insulating resistive-field-plate structure 3 is electrically connected to the substrate 1, and an end of the semi-insulating resistive-field-plate structure 4 away from the substrate 1 is electrically connected to the trench gate structure 4.

The trench gate structure 4 and the semi-insulating resistive-field-plate structure 3 share an isolation dielectric layer 300.

As shown in FIG. 18, a trench T is formed in the epitaxial layer 2, and the trench T vertically extends through the MOS source region 22, the MOS channel region 21, and the epitaxial layer 2 to the substrate 1; the semi-insulating resistive-field-plate structure 3 and the trench gate structure 4 are sequentially disposed in the trench T along a bottom-to-top direction of the trench T.

In an embodiment, as shown in FIG. 18, the semi-insulating resistive-field-plate structure 3 includes the isolation dielectric layer 300 and a semi-insulating resistive-field-plate layer 31 whose side wall is surrounded by the isolation dielectric layer 300, and the trench gate structure 4 includes the isolation dielectric layer 300, a second trench gate layer 42, and a third trench gate layer 43; the second trench gate layer 42 is electrically connected to the semi-insulating resistive-field-plate layer 31, and the semi-insulating resistive-field-plate layer 31 is electrically connected to the substrate 1 at a bottom of the trench T.

In an embodiment, the trench gate structure 4 includes the isolation dielectric layer 300, a second trench gate layer 42, and a third trench gate layer 43. The trench gate structure 4 is a gate structure based on a second doped polysilicon.

The preparation method of the shared-dielectric MOSFET device with the resistive-field-plate provided by Embodiment 2,is similar to the Embodiment 1. Embodiment 2 differs from Embodiment 1 in that: the preparation method of Embodiment 2 further includes step S44 of forming the trench gate structure 4 in the trench T.

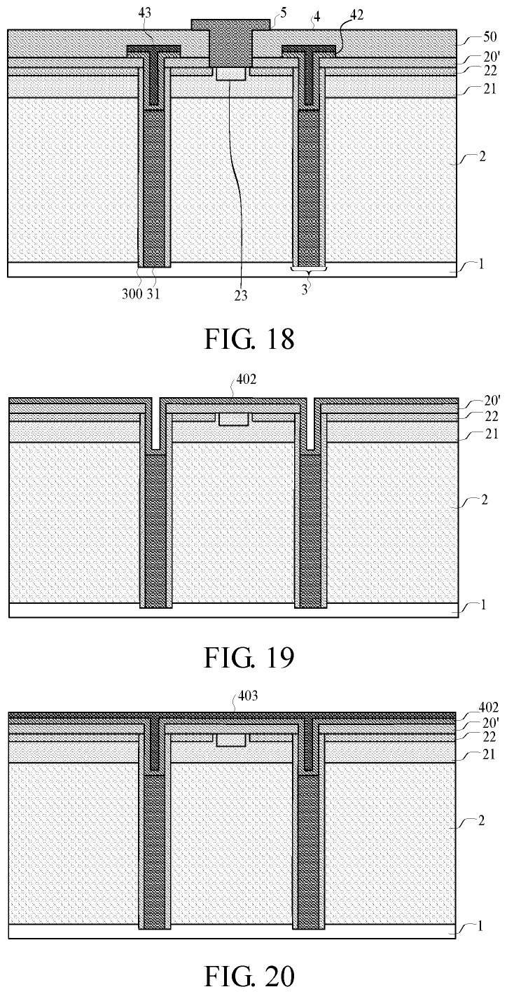

Step S44, as shown in FIGS. 19-21, sequentially forming the second trench gate layer 42 and the third trench gate layer 43 over the semi-insulating resistive-field-plate layer 31, wherein a sidewall of the second trench gate layer 4 is surrounded by the isolation dielectric layer 300, a sidewall of the third trench gate layer 4 is surrounded by the second trench gate layer 42, and a bottom of the second trench gate layer 42 is electrically connected to the semi-insulating resistive-field-plate layer 31.

The semi-insulating resistive-field-plate layer 31 and the isolation dielectric layer 300 constitute the semi-insulating resistive-field-plate structure 3; the second trench gate layer 42, the third trench gate layer 43, and the isolation dielectric layer 300 constitute the trench gate structure 4.

As shown in FIGS. 19-21, the step S44 of sequentially forming the second trench gate layer 42 and the third trench gate layer 43 over the semi-insulating resistive-field-plate layer 31 includes:

step S441, as shown in FIG. 19, filling a second doped polysilicon material 402 in the trench T over the semi-insulating resistive-field-plate layer 31, wherein the second doped polysilicon material 402 at least covers the top surface of the semi-insulating resistive-field-plate layer 31, and part of the sidewall of the trench T not covered by the semi-insulating resistive-field-plate layer 31;

step S442, as shown in FIG. 20, filling a third doped polysilicon material 403 over the second doped polysilicon material 402, wherein the semi-insulating resistive-field-plate layer 31, the second doped polysilicon material 402, and the third doped polysilicon material 403 at least fill the trench T (meaning it at least occupies any space left of the trench T);

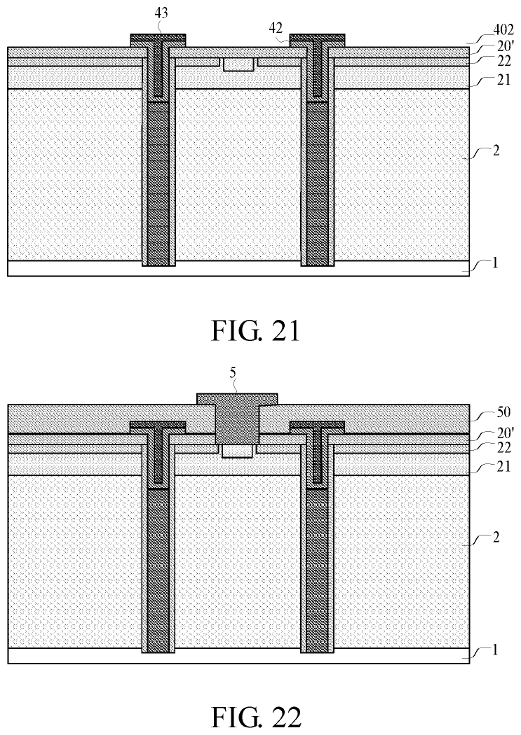

step S443, as shown in FIG. 21, etching the third doped polysilicon material 403 to form the third trench gate layer 43, and etching the second doped polysilicon material 402 to form the second trench gate layer 42.

In an embodiment, as shown in FIG. 19, in step S441, the second doped polysilicon material 402 is deposited in the trench T over the semi-insulating resistive-field-plate layer 31, and the second doped polysilicon material 402 at least covers the top surface of the semi-insulating resistive-field-plate layer 31 and part of the sidewall of the trench T not covered by the semi-insulating resistive-field-plate layer 31; for example, the second doped polysilicon material 402 with a thickness of 450-600 nm can be formed by low-pressure chemical vapor in-situ phosphorus doping deposition, and if there is no in-situ doping equipment, a phosphorus diffusion doping can be performed after the second doped polysilicon material 402 is deposited.

Further, as shown in FIG. 20, in step S442, the third doped polysilicon material 403 is deposited in the trench T over the second doped polysilicon material 402, and the semi-insulating resistive-field-plate layer 31, the second doped polysilicon material 402, and the third doped polysilicon material 403 at least fill the trench T; for example, the third doped polysilicon material 403 with a thickness of 500-650 nm can be formed by low-pressure chemical vapor in-situ phosphorus doping deposition, and if there is no in-situ doping equipment, the top portion of the trench T not covered by the semi-insulating resistive-field-plate layer 31 and the second doped polysilicon material 402 can be enclosed for phosphorus ion implantation under the conditions of 100 KeV and 5×1015 cm−2.

As shown in FIG. 21, in step S443, the third doped polysilicon material 403 and the second doped polysilicon material 402 are etched by photolithography and dry etching to respectively form the third trench gate layer 43 and the second trench gate layer 42, and the trench gate structure 4 shown in FIG. 21 includes the third trench gate layer 43 and the second trench gate layer 42.

The third doped polysilicon material 403 is etched to form the third trench gate layer 43; the second doped polysilicon material 402 is etched to form the second trench gate layer 42; the second trench gate layer 42 is electrically connected to the semi-insulating resistive-field-plate layer 31.

As shown in FIG. 22, an isolation dielectric layer 50 is formed on the oxide layer 20′ and the trench gate structure 4 by deposition; a source contact hole is formed in the isolation dielectric layer 50; a metal layer is formed in the source contact hole by deposition and the metal layer is etched by photolithography to form a source electrode 5. The process of forming the gate electrode is similar to that of the source electrode.

In summary, in the shared-dielectric MOSFET device with the resistive-field-plate and the preparation method thereof of the present disclosure, a semi-insulating resistive-field-plate electrically connected to the trench gate structure and the drain structure is added in the drift region of the existing trench gate MOS devices; when the trench gate structure controls the MOS channel to be turned on or off, the semi-insulating resistive-field-plate can adjust the doping concentration of the drift region, to modulate the conductance of the on-state drift region and the distribution of the off-state high-voltage blocking electric field, thereby obtaining a lower on-resistance. In addition, the modern 2.5-dimensional processing technology based on deep trench etching is adopted in the present disclosure, which is conducive to miniaturization designs and high density designs of the structure and is more suitable for the More than Moore development of modern integrated semiconductor devices.

The above embodiments are illustrative of the principles and benefits of the disclosure rather than restrictive of the scope of the disclosure. Persons skilled in the art can make modifications and changes to the embodiments without departing from the spirit and scope of the disclosure. Therefore, all equivalent modifications and changes made by persons skilled in the art without departing from the spirit and technical concepts disclosed in the disclosure shall still be deemed falling within the scope of the claims of the disclosure.

1. A shared-dielectric metal-oxide-semiconductor field-effect transistor (MOSFET) device with a resistive-field-plate, comprising:
a substrate;
an epitaxial layer, disposed over the substrate;
a MOS source region, disposed in a top portion of the epitaxial layer;
a MOS channel region, disposed in the epitaxial layer and below the MOS source region;
a trench gate structure, disposed on the top portion of the epitaxial layer; wherein the trench gate structure covers side surfaces of the MOS source region and the MOS channel region; and
a semi-insulating resistive-field-plate structure, disposed in the epitaxial layer and located below the trench gate structure; wherein the semi-insulating resistive-field-plate structure is electrically connected to the substrate, and an end of the semi-insulating resistive-field-plate structure away from the substrate is electrically connected to the trench gate structure;
wherein the trench gate structure and the semi-insulating resistive-field-plate structure share an isolation dielectric layer;
wherein a trench is formed in the epitaxial layer, and the trench vertically extends through the MOS source region, the MOS channel region, and the epitaxial layer to the substrate; the semi-insulating resistive-field-plate structure and the trench gate structure are sequentially disposed in the trench along a bottom-to-top direction of the trench.

2. The shared-dielectric MOSFET device with the resistive-field-plate according to claim 1, wherein the semi-insulating resistive-field-plate structure comprises the isolation dielectric layer and a semi-insulating resistive-field-plate layer whose side wall is surrounded by the isolation dielectric layer, and the trench gate structure comprises the isolation dielectric layer and a first trench gate layer; wherein the first trench gate layer is electrically connected to the semi-insulating resistive-field-plate layer, and the semi-insulating resistive-field-plate layer is electrically connected to the substrate at a bottom of the trench.

3. The shared-dielectric MOSFET device with the resistive-field-plate according to claim 1, wherein the semi-insulating resistive-field-plate structure comprises the isolation dielectric layer and a semi-insulating resistive-field-plate layer whose side wall is surrounded by the isolation dielectric layer, and the trench gate structure comprises the isolation dielectric layer, a second trench gate layer, and a third trench gate layer; wherein the third trench gate layer is electrically connected to the semi-insulating resistive-field-plate layer, and the semi-insulating resistive-field-plate layer is electrically connected to the substrate at a bottom of the trench.

4. The shared-dielectric MOSFET device with the resistive-field-plate according to claim 2, further comprising:
a MOS channel contact region, disposed in the top portion of the epitaxial layer; wherein the MOS channel contact region is in contact with the MOS channel region.

5. The shared-dielectric MOSFET device with the resistive-field-plate according to claim 4, further comprising:
a source electrode, disposed over the MOS channel contact region and electrically connected to the MOS source region;
a gate electrode, disposed over the trench gate structure and electrically connected to the trench gate structure; and
a drain electrode, disposed on a side of the substrate away from the epitaxial layer.

6. A preparation method of a shared-dielectric MOSFET device with a resistive-field-plate, comprising:
providing a substrate and forming an epitaxial layer on the substrate;
forming a MOS channel region, a MOS source region, and a MOS channel contact region within a top portion of the epitaxial layer;
forming a trench in the epitaxial layer; wherein the trench vertically extends through the MOS source region, the MOS channel region, and the epitaxial layer to the substrate;
sequentially forming a semi-insulating resistive-field-plate structure and a trench gate structure in the trench along a bottom-to-top direction of the trench; wherein the semi-insulating resistive-field-plate structure is electrically connected to the trench gate structure, and an end of the semi-insulating resistive-field-plate structure away from the trench gate structure is electrically connected to the substrate; and
forming a source electrode, a gate electrode, and a drain electrode;
wherein the trench gate structure and the semi-insulating resistive-field-plate structure share an isolation dielectric layer.

7. The preparation method of the shared-dielectric MOSFET device with the resistive-field-plate according to claim 6, wherein the step of forming the MOS channel region, the MOS source region, and the MOS channel contact region within the top portion of the epitaxial layer comprises:
forming the MOS channel region within the top portion of the epitaxial layer by a first ion implantation and a first ion diffusion;
forming the MOS source region disposed over the MOS channel region by a second ion implantation; and
forming the MOS channel contact region by a third ion implantation; wherein the MOS channel contact region is in contact with the MOS channel region.

8. The preparation method of the shared-dielectric MOSFET device with the resistive-field-plate according to claim 6, wherein the step of sequentially forming the semi-insulating resistive-field-plate structure and the trench gate structure in the trench along the bottom-to-top direction of the trench comprises:
oxidating a bottom and a sidewall of the trench to form the isolation dielectric layer;
etching and removing part of the isolation dielectric layer at the bottom of the trench;
filling the trench to form a semi-insulating resistive-field layer; wherein a top surface of the semi-insulating resistive-field layer is lower than a bottom surface of the MOS channel region; and
forming a first trench gate layer over the semi-insulating resistive-field-plate layer and electrically connected to the semi-insulating resistive-field-plate layer;
wherein the semi-insulating resistive-field-plate layer and the isolation dielectric layer constitute the semi-insulating resistive-field-plate structure, and the first trench gate layer and the isolation dielectric layer constitute the trench gate structure.

9. The preparation method of the shared-dielectric MOSFET device with the resistive-field-plate according to claim 7, wherein the step of sequentially forming the semi-insulating resistive-field-plate structure and the trench gate structure in the trench along the bottom-to-top direction of the trench comprises:
oxidating a bottom and a sidewall of the trench to form the isolation dielectric layer;
etching and removing part of the isolation dielectric layer at the bottom of the trench;
filling the trench to form a semi-insulating resistive-field-plate layer; wherein a top surface of the semi-insulating resistive-field-plate layer is lower than a bottom surface of the MOS channel region; and
sequentially forming a second trench gate layer and a third trench gate layer over the semi-insulating resistive-field-plate layer; wherein a sidewall of the second trench gate layer is surrounded by the isolation dielectric layer, a sidewall of the third trench gate layer is surrounded by the second trench gate layer, and a bottom of the second trench gate layer is electrically connected to the semi-insulating resistive-field-plate layer;
wherein the semi-insulating resistive-field-plate layer and the isolation dielectric layer constitute the semi-insulating resistive-field-plate structure; the second trench gate layer, the third trench gate layer, and the isolation dielectric layer constitute the trench gate structure.

10. The preparation method of the shared-dielectric MOSFET device with the resistive-field-plate according to claim 8, wherein the step of forming the semi-insulating resistive-field layer in the trench comprises:
filling the trench with a semi-insulating polysilicon material;
etching and removing a part of the semi-insulating polysilicon material filled in the trench, so that a top surface of remaining semi-insulating polysilicon material filled in the trench is below the bottom surface of the MOS channel region;
wherein the top surface of the remaining semi-insulating polysilicon material filled in the trench is the top surface of the semi-insulating resistive-field layer.

11. The preparation method of the shared-dielectric MOSFET device with the resistive-field-plate according to claim 8, wherein the step of forming the first trench gate layer over the semi-insulating resistive-field-plate layer comprises:
filling a first doped polysilicon material in the trench over the semi-insulating resistive-field-plate layer, wherein the first doped polysilicon material at least covers the top surface of the semi-insulating resistive-field-plate layer; and
etching the first doped polysilicon material to form the first trench gate layer.

12. The preparation method of the shared-dielectric MOSFET device with the resistive-field-plate according to claim 9, wherein the step of sequentially forming the second trench gate layer and the third trench gate layer over the semi-insulating resistive-field-plate layer comprises:
filling a second doped polysilicon material in the trench over the semi-insulating resistive-field-plate layer, wherein the second doped polysilicon material at least covers the top surface of the semi-insulating resistive-field-plate layer, and part of the sidewall of the trench not covered by the semi-insulating resistive-field-plate layer;
filling a third doped polysilicon material over the second doped polysilicon material, wherein the semi-insulating resistive-field-plate layer, the second doped polysilicon material, and the third doped polysilicon material at least fill the trench; and
etching the third doped polysilicon material to form the third trench gate layer, and etching the second doped polysilicon material to form the second trench gate layer.
